(19) United States
(12) Patent Application Publication
(10) Pub. No.: US 2013/0279120 A1
(43) Pub. Date: Oct. 24, 2013

(54) SHELL FOR FIXING MAIN BOARD THERETO AND ELECTRONIC DEVICE HAVING SAME

(71) Applicant: YUAN-MING WANG, Shenzhen City (CN)

(72) Inventor: YUAN-MING WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (TW)

(21) Appl. No.: 13/494,035

(22) Filed: Jun. 12, 2012

(30) Foreign Application Priority Data
Apr. 18, 2012 (CN) 201210113960.X

(51) Int. Cl. H05K 1/14

(52) U.S. Cl. 361/736

(57) ABSTRACT

A shell for fixing main board of an electronic device including a base wall, and sidewalls around the base wall, is provided. The base wall includes supporting projections. The internal surface of sidewalls includes restriction elements. The main board is laid on the supporting projections and abuts against the restriction elements. The base wall includes positioning pins and the main board defines positioning holes into which the positioning pins can be engaged.

### BACKGROUND

1. Technical Field

The present disclosure relates to shells and, particularly, to a shell for fixing a main board of an electronic device and the electronic device with the shell.

2. Description of Related Art

Main boards of the electronic devices may be fixed to shells or housings of the electronic devices by screws. And so, tools such as screwdriver are necessary, which is very troublesome and time-consuming. Moreover, it is more likely to destroy the main board during the assembly. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a partial isometric view of an electronic device with a main board fixed to a shell of the electronic device according to an exemplary embodiment.

FIG. 2 is an exploded isometric view of the electronic device of FIG. 1.

FIG. 3 is an enlarged view of the circled portion III of FIG. 2.

FIG. 4 is a cross-sectional view taken along the line IV-IV of FIG. 1.

### DETAILED DESCRIPTION

The disclosure is illustrated by way of example and not by way of limitation in the figures of the accompanying drawings in which like references indicate similar elements. It should be noted that references to “a” or “one” embodiment in this disclosure are not necessarily to the same embodiment, and such references mean “at least one”.

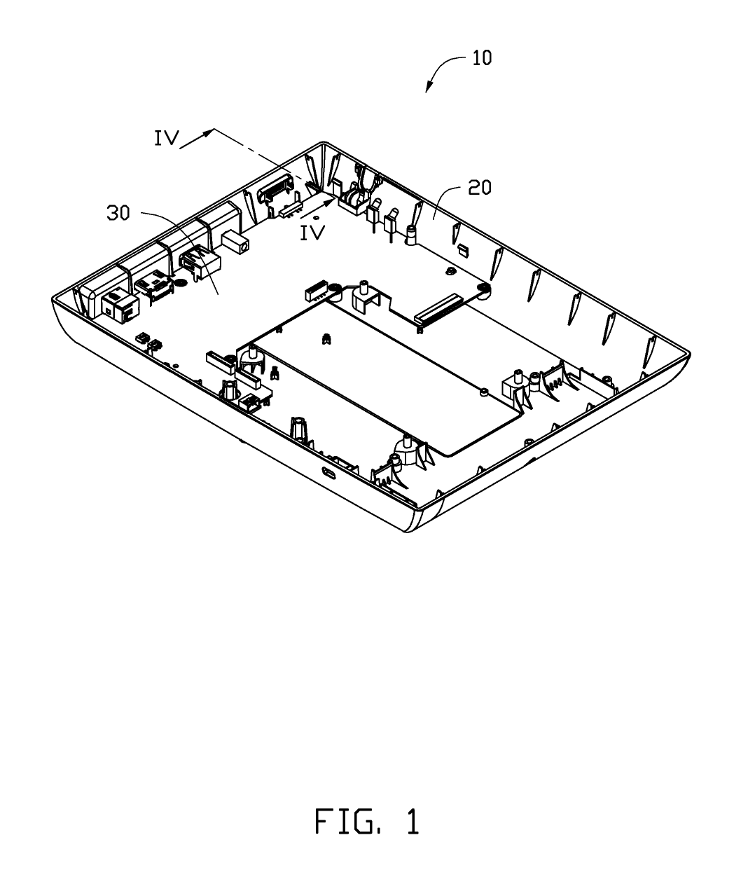

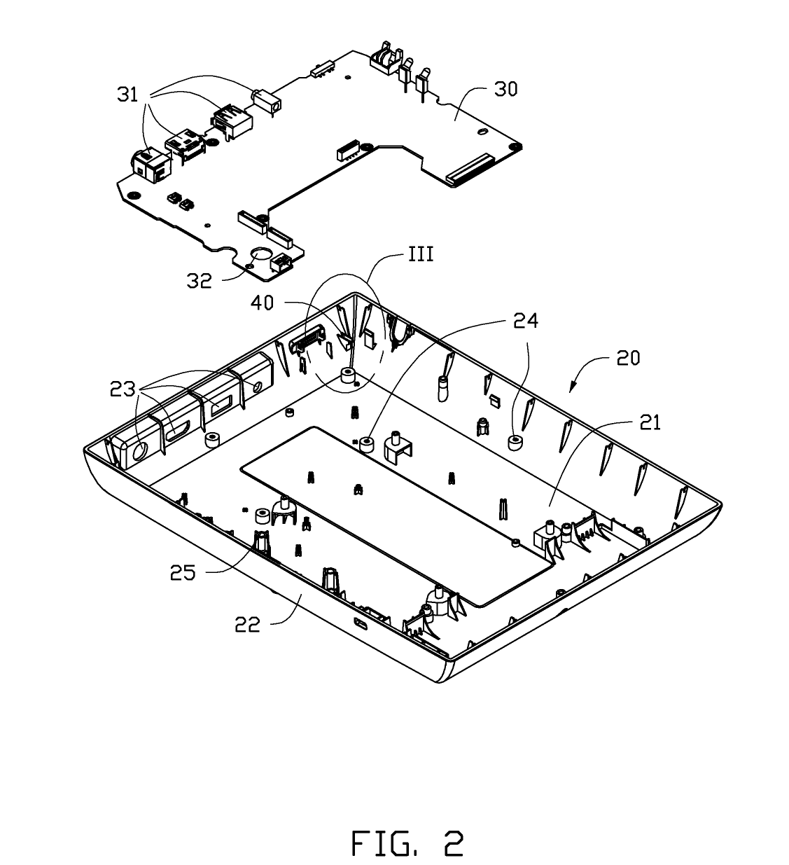

Referring to FIGS. 1 and 2, according to an exemplary embodiment, an electronic device 10 includes an upper shell, a lower shell 20 and a main board 30. The upper shell and the lower shell 20 cooperatively forms a housing receiving the main board 30. A plurality of connectors 31 are situated on an edge of the main board 30. The lower shell 20 includes a base wall 21 and a plurality of sidewalls 22 extending from and surrounding the base wall 21. The sidewalls 22 define a plurality of jacks 32 engaging with the connectors 31. Thus, the electronic device 10 can transmit data or signals with other devices.

The base wall 21 includes a plurality of supporting projections 24 and positioning pins 25. The main board 30 is positioned on the supporting projections 24. The main board 30 defines positioning holes 32 engaging with the positioning pins 25. Thus, the horizontal plane movements of the main board 30 are limited.

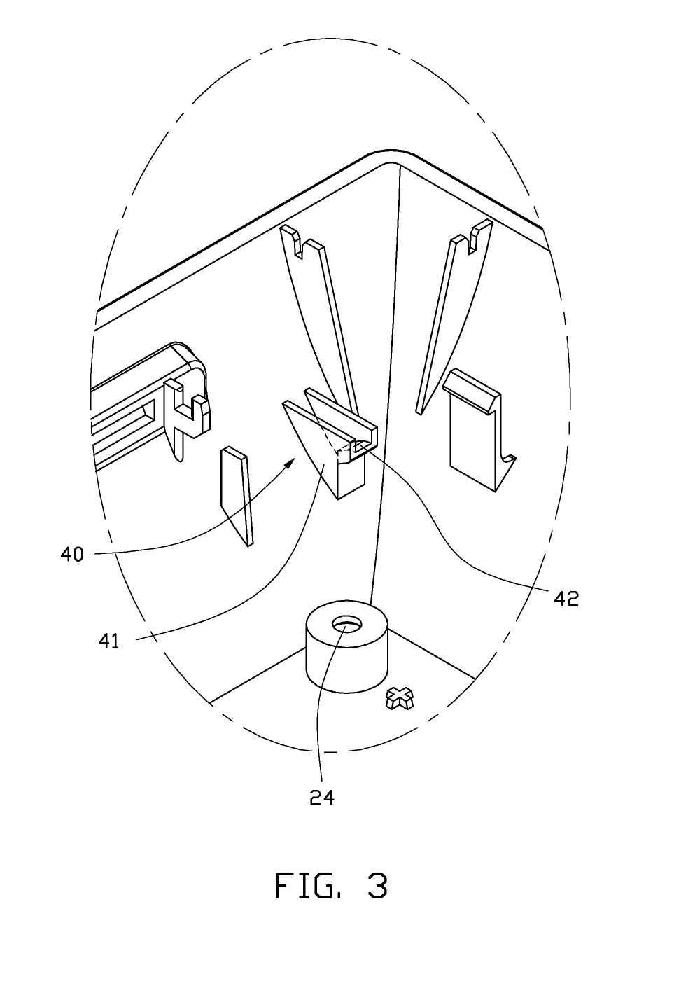

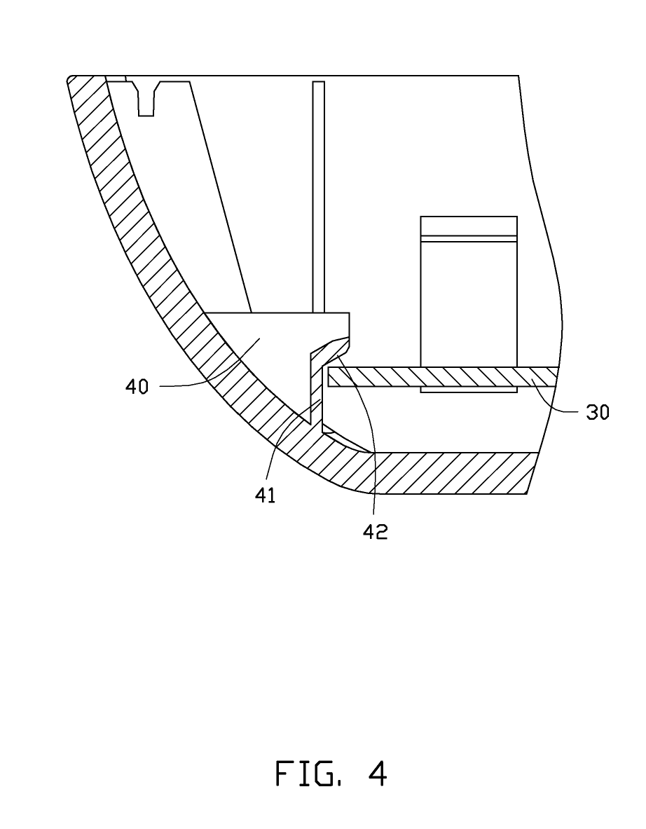

Referring to FIGS. 3 and 4, the sidewall 22 includes a plurality of restriction elements 40. The restriction elements 40 are positioned above the main board 30. Each restriction element 40 includes a protrusion 41 protruding from an internal surface of the sidewall 22 and a restriction portion 42 obliquely extending upward from a distal end of the protrusion 41. The main board 30 abuts against the restriction elements 40. Thus, the vertical movement of the main board 30 relating to the base wall 21 is also limited. For the restriction portion 42 inclines upward, space is reserved in the vertical direction between the restriction portion 42 and the main board 30 when installing the main board 30 to the lower shell 20 and then the positioning pins 25 can be smoothly inserted into the positioning holes 32.

The main board 30 is vertically limited in movement by supporting projections 24 and the limiting elements 40, and in the horizontal plane by the positioning pins 25. Screws are not required to fix the main board 30 to the lower shell 20 and the way of assembly is easier.

The disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A shell for fixing a main board received in the shell, comprising:
a base wall;
a plurality of supporting projections formed on the base wall for supporting an underside of the main board;
a plurality of sidewalls extending from and surrounding the base wall; and
a plurality of restriction elements protruding from internal surfaces of the sidewalls, the restriction elements configured for abutting against an upper side of the main board, thereby blocking the main board from moving away from the base wall .

2. The shell as described in claim 1, wherein each restriction element includes a protrusion protruding from the internal surface of the sidewall and a restriction portion obliquely extending from a distal end of the protrusion.

3. The shell as described in claim 1, wherein the base wall includes a plurality of positioning pins for engaging with positioning holes defined in the main board.

4. An electronic device, comprising:
a main board;
an upper shell;
a lower shell, the upper shell and the lower shell cooperative forming a housing receiving the main body therein, the lower shell comprising:
a base wall;
a plurality of supporting projections formed on the base wall for supporting an underside of the main board;
a plurality of sidewalls extending from and surrounding the base wall;
a plurality of restriction elements protruding from internal surfaces of the sidewalls;
the restriction elements abutting against an upper side of the main board, thereby blocking the main board from moving away from the base wall.

5. The electronic device as described in claim 4, wherein each restriction element includes a protrusion protruding from the internal surface of the sidewall and a restriction portion obliquely extending from a distal end of the protrusion.

6. The electronic device as described in claim 4, wherein the base wall including a plurality of positioning pins for engaging with the positioning holes defined in the main board.
